(19) United States
(12) Patent Application Publication
(10) Pub. No.: US 2025/0070805 A1
(43) Pub. Date: Feb. 27, 2025

(54) RADIO FREQUENCY MODULE

(71) Applicant: Murata Manufacturing Co., Ltd., Kyoto (JP)

(72) Inventor: Yoshihito OTSUBO, Kyoto (JP)

(21) Appl. No.: 18/948,984

(22) Filed: Nov. 15, 2024

Related U.S. Application Data
(63) Continuation of application No. PCT/JP2023/017877, filed on May 12, 2023.

(30) Foreign Application Priority Data
May 19, 2022 (JP) 2022-082645

(51) Int. Cl. H04B 1/04; H04B 1/16; H05K 1/02; H05K 1/16

(52) U.S. Cl. CPC H04B 1/0458; H04B 1/1607; H05K 1/025; H05K 1/162; H05K 1/165

(57) ABSTRACT

A radio frequency module includes a wiring board, a first electronic component and a second electronic component, and a third electronic component connected to a matching circuit. The wiring board includes a core board having not only a first principal surface and a second principal surface but also a through hole, a first buildup layer stacked on the first principal surface, and a second buildup layer stacked on the second principal surface. At least one of the first electronic component or the second electronic component is disposed partially inside the through hole. The third electronic component is disposed on the first buildup layer. The second electronic component is stacked on one side, where the third electronic component is located, of the first electronic component in a thickness direction defined for the core board. The second electronic component is a constituent component of the matching circuit.

### CROSS REFERENCE TO RELATED APPLICATION

This is a continuation of International Application No. PCT/JP2023/017877 filed on May 12, 2023 which claims priority from Japanese Patent Application No. 2022-082645 filed on May 19, 2022. The contents of these applications are incorporated herein by reference in their entireties.

### BACKGROUND OF THE DISCLOSURE

### Field of the Disclosure

The present disclosure generally relates to a radio frequency (RF) module and more particularly relates to an RF module including a core board and a plurality of buildup layers.

### Description of the Related Art

JP 2016-25143 A discloses a circuit board in which a buildup layer is stacked one on top of another on a core board with a cavity (through hole). In the circuit board of JP 2016-25143 A, a composite component housed inside the cavity includes an electronic component and a metal block which are stacked one on top of the other.

### BRIEF SUMMARY OF THE DISCLOSURE

Recently, there has been an increasing demand for further reducing the height of RF modules.

A possible benefit of the present disclosure is to provide an RF module which may have a further reduced height.

A radio frequency module according to an aspect of the present disclosure includes a wiring board, a first electronic component and a second electronic component, and a third electronic component. The first electronic component and the second electronic component are built in the wiring board. The third electronic component is disposed on the wiring board and connected to a matching circuit. The wiring board includes a core board, a first buildup layer, and a second buildup layer. The core board has not only a first principal surface and a second principal surface facing each other but also a through hole. The first buildup layer is stacked on the first principal surface of the core board. The second buildup layer is stacked on the second principal surface of the core board. At least one of the first electronic component or the second electronic component is disposed at least partially inside the through hole of the core board. The third electronic component is disposed on the first buildup layer. The second electronic component is stacked on one side, where the third electronic component is located, of the first electronic component in a thickness direction defined for the core board. The second electronic component is a constituent component of the matching circuit.

A radio frequency module according to another aspect of the present disclosure includes a wiring board, a first electronic component and a second electronic component, and an external connection terminal. The first electronic component and the second electronic component are built in the wiring board. The external connection terminal is disposed on the wiring board. The wiring board includes a core board, a first buildup layer, and a second buildup layer. The core board has not only a first principal surface and a second principal surface facing each other but also a through hole. The first buildup layer is stacked on the first principal surface of the core board. The second buildup layer is stacked on the second principal surface of the core board. At least one of the first electronic component or the second electronic component is disposed at least partially inside the through hole of the core board. The external connection terminal is disposed on the second buildup layer. The second electronic component is stacked on one side, opposite from another side where the external connection terminal is located, of the first electronic component in a thickness direction defined for the core board. The first electronic component is an IC chip connected to the matching circuit.

An RF module according to an aspect of the present disclosure contributes to reducing its height.

### BRIEF DESCRIPTION OF THE SEVERAL VIEWS OF THE DRAWINGS

FIG. 1 is a cross-sectional view of an RF module according to a first embodiment;

FIG. 2 is a cross-sectional view of an RF module according to a second embodiment;

FIG. 3 is a cross-sectional view of an RF module according to a third embodiment;

FIG. 4 is a cross-sectional view of an RF module according to a fourth embodiment;

FIG. 5 is a cross-sectional view of an RF module according to a fifth embodiment; and

FIG. 6 is a cross-sectional view of an RF module according to a sixth embodiment.

### DETAILED DESCRIPTION OF THE DISCLOSURE

RF modules and communications devices according to first to sixth embodiments will now be described with reference to the accompanying drawings. The drawings to be referred to in the following description of the first to sixth embodiments are all schematic representations. Thus, the ratio of the dimensions (including thicknesses) of respective constituent elements illustrated on the drawings does not always reflect their actual dimensional ratio.

### First Embodiment

### (1) Overview

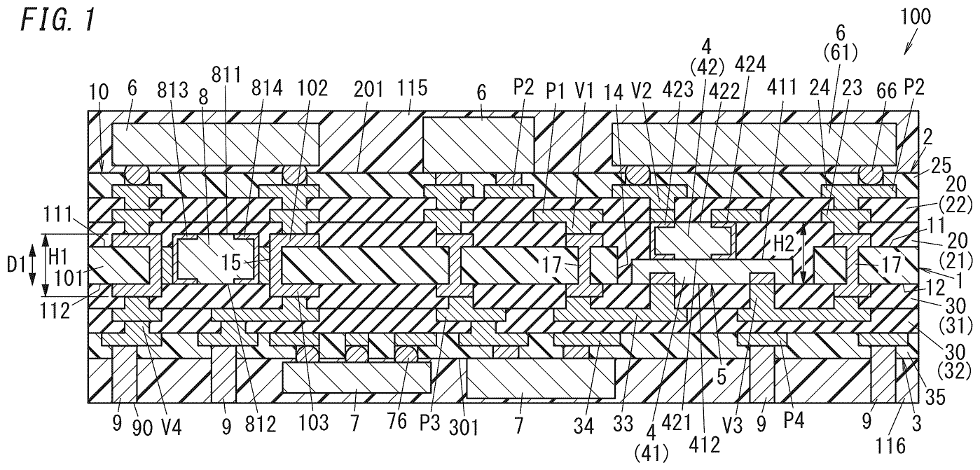

As shown in FIG. 1, an RF module 100 according to a first embodiment includes a wiring board 10, a plurality of (e.g., two in FIG. 1) electronic components 4, a plurality of (e.g., three in FIG. 1) electronic components 6, a plurality of (e.g., two in FIG. 1) electronic components 7, another electronic component 8, and a plurality of (e.g., four in FIG. 1) external connection terminals 9. The plurality of electronic components 6 are arranged on the wiring board 10. The plurality of electronic components 7 and the plurality of external connection terminals 9 are also arranged on the wiring board 10. The plurality of electronic components 4 and the electronic component 8 are built in the wiring board 10.

The wiring board 10 includes a core board 1, a first buildup layer 2, and a second buildup layer 3. The core board 1 has not only a first principal surface 11 and a second principal surface 12 facing each other but also a through hole 14 as well. As used herein, the phrase “facing each other” refers to facing each other geometrically, not physically. The first buildup layer 2 is stacked on the first principal surface 11 of the core board 1. The second buildup layer 3 is stacked on the second principal surface 12 of the core board 1.

In the thickness direction D1 defined for the core board 1, one electronic component 4 is stacked on another electronic component 4. In the example shown in FIG. 1, in the thickness direction D1 defined for the core board 1, the electronic component 42 is stacked on one side, where the electronic components 6 are located, of the electronic component 41. In addition, the plurality of electronic components 4 are built in the wiring board 10. More specifically, at least part of the space occupied by the plurality of electronic components 4 (hereinafter referred to as an “electronic component region 5”) is located inside the through hole 14 of the core board 1. In other words, at least one of the plurality of electronic components 4 is disposed at least partially inside the through hole 14 of the core board 1.

The electronic components 6 are arranged on one principal surface 201, opposite from the other principal surface facing the core board 1, of the first buildup layer 2. The electronic components 7 and the external connection terminals 9 are arranged on one principal surface 301, opposite from the other principal surface facing the core board 1, of the second buildup layer 3. The RF module 100 further includes a first resin layer 115 and a second resin layer 116. The first resin layer 115 is stacked on the first buildup layer 2 to cover the electronic components 6 at least partially. The second resin layer 116 is stacked on the second buildup layer 3 to cover each of the electronic components 7 and the plurality of external connection terminals 9 partially.

The RF module 100 may be used, for example, in a communications device. The communications device may be, without limitation, a cellphone (such as a smartphone), for example. Alternatively, the communications device may also be a wearable terminal (such as a smartwatch). The RF module 100 is a module compatible with, for example, a fourth-generation mobile communications (4G) standard or a fifth-generation mobile communications (5G) standard. Examples of the 4G standard include the third-generation partnership project (3GPP (R)) standard and the long-term evolution (LTE (R)) standard. Examples of the 5G standards include the 5G new radio (NR) standard. The RF module 100 is a module compatible with the carrier aggregation and dual connectivity, for example.

### (2) Details

Next, an RF module 100 according to a first embodiment will be described in further detail with reference to FIG. 1.

### (2.1) Core Board

As shown in FIG. 1, the core board 1 has a first principal surface 11 and a second principal surface 12. When viewed in plan in the thickness direction D1 defined for the core board 1, the outer edges of the core board 1 have a quadrangular shape, for example.

The core board 1 includes a dielectric substrate 101, a first conductive layer 102, a second conductive layer 103, and a plurality of feedthrough via conductors 17. In the core board 1, the first conductive layer 102 is disposed on one principal surface 111 of the dielectric substrate 101 and the second conductive layer 103 is disposed on the other principal surface 112 of the dielectric substrate 101. Each of the first conductive layer 102 and the second conductive layer 103 is formed to have one or more predetermined patterns which are defined on a layer-by-layer basis. The core board 1 may be, for example, a double-sided printed wiring board. Examples of materials for the dielectric substrate 101 include an epoxy resin, a polyimide resin, and a composite material of an epoxy resin and a glass fiber. A material for the first conductive layer 102 and the second conductive layer 103 may be copper, for example. A material for the feedthrough via conductors 17 may include copper, for example.

The first principal surface 11 and second principal surface 12 of the core board 1 face each other in the thickness direction D1 defined for the core board 1. Optionally, the first principal surface 11 and second principal surface 12 of the core board 1 may have microscopic unevenness or have only microscopic recesses or projections.

The core board 1 has a through hole (first through hole) 14 and a second through hole 15. The plurality of electronic components 4 are arranged inside the first through hole 14 of the core board 1. The electronic component 8 is disposed inside the second through hole 15 of the core board 1.

### (2.2) Electronic Components

The plurality of electronic components 4 includes the electronic component 41 and the electronic component 42. As shown in FIG. 1, the electronic component 42 is stacked on the electronic component 41 in the thickness direction D1 defined for the core board 1. More specifically, the electronic component 42 is stacked on one side, where the electronic components 61 are located, of the electronic component 41. The electronic component 41 has principal surfaces 411, 412 facing each other in the thickness direction D1 defined for the core board 1. The electronic component 42 has principal surfaces 421, 422 facing each other in the thickness direction D1 defined for the core board 1. Also, the principal surface 411 of the electronic component 41 and the principal surface 421 of the electronic component 42 are in contact with each other.

The electronic component 41 may be, for example, an IC chip. The electronic component 41 includes a plurality of electrodes. For example, the respective surfaces of the electrodes form part of the principal surface 412. The electrodes of the electronic component 41 are connected to a second conductor layer 33 of the second buildup layer 3.

The electronic component 42 may be, for example, a chip capacitor. The electronic component 42 includes an electrode 423 and an electrode 424. Each of the electrodes 423, 424 of the electronic component 42 is connected to the first conductor layer 23 of the first buildup layer 2. The electronic component 42 is connected to the electronic component 61 as will be described later.

As shown in FIG. 1, the plurality of electronic components 4 are disposed at least partially inside the through hole 14 of the core board 1. More specifically, part of an electronic component region 5 is present inside the through hole 14 of the core board 1 in the thickness direction D1 defined for the core board 1. When viewed in plan in the thickness direction D1 defined for the core board 1, at least part of the electronic component region 5 overlaps with the through hole 14 either partially or entirely. As shown in FIG. 1, the total thickness H2 of the plurality of electronic components 4 is greater than the thickness H1 of the core board 1. As used herein, the “total thickness H2 of the plurality of electronic components 4” refers to a maximum distance between two points inside the electronic component region 5 as measured in the thickness direction D1 defined for the core board 1. In the example shown in FIG. 1, the distance between the principal surface 412, facing away from the electronic component 42, of the electronic component 41 and the principal surface 422, facing away from the electronic component 41, of the electronic component 42 corresponds to the total thickness H2 of the plurality of electronic components 4 (i.e., the total thickness H2 of the electronic components 41,42).

The electronic component 8 may be a chip capacitor. The electronic component 8 has an electrode 813 and an electrode 814. Each of these electrodes 813, 814 of the electronic component 8 may be connected, via solder, for example, to the feedthrough via conductor 17 formed on the inner peripheral surface of the second through hole 15 of the core board 1. The electronic component 8 has a substantially rectangular parallelepiped outer shape. Part of a first dielectric layer 20 of the first buildup layer 2 is interposed between the electronic component 8 and the inner peripheral surface of the second through hole 15 of the core board 1. The electronic component 8 has a principal surface 811 and a principal surface 812 facing each other in the thickness direction D1 defined for the core board 1.

### (2.3) First Buildup Layer

The first buildup layer 2 is stacked on the first principal surface 11 of the core board 1, the principal surface 411 of the electronic component 41, the principal surface 422 of the electronic component 42, and the principal surface 811 of the electronic component 8. The first buildup layer 2 includes a plurality of (e.g., two) first dielectric layers 20. If the two first dielectric layers 20 need to be distinguished from each other, then the two first dielectric layers 20 will be hereinafter referred to as a “first dielectric layer 21” and a “first dielectric layer 22,” respectively. In the first buildup layer 2, the first dielectric layer 21 is a first dielectric layer 20 located closest to the first principal surface 21 of the core board 1 in the thickness direction D1 defined for the core board 1. On the other hand, in the first buildup layer 2, the first dielectric layer 22 is a first dielectric layer 20 located most distant from the first principal surface 11 of the core board 1 in the thickness direction D1 defined for the core board 1.

In addition, the first buildup layer 2 further includes a plurality of (e.g., two) first conductor layers 23, 24. The first conductor layer 23 is interposed between the first dielectric layers 21, 22. The first conductor layer 24 is formed on the first dielectric layer 22. These two first conductor layers 23, 24 are formed in one or more predetermined patterns which are defined on a layer-by-layer basis. The first conductor layer 23 includes one or more rewiring portions (conductor portions) P1 as the one or more predetermined patterns. The first conductor layer 24 includes one or more rewiring portions (conductor portions) P2 as the one or more predetermined patterns. In addition, the first buildup layer 2 further includes a plurality of via conductors V1 which connect the first conductor layer 23 and the first conductive layer 102 of the core board 1 to each other and a plurality of via conductors V2 which connect the first conductor layers 24, 23 to each other.

Examples of materials for the plurality of first dielectric layers 20 include an epoxy resin, a phenolic resin, a urethane resin, a silicone resin, and a polyimide resin. A material for the plurality of first conductor layers 23, 24 may include, for example, copper.

The first buildup layer 2 further includes a first resist layer 25. The first resist layer 25 is stacked on the first dielectric layer 22 and the first conductor layer 24. The first resist layer 25 is formed in a predetermined pattern and has a plurality of openings which expose respective parts of the plurality of rewiring portions P2. The first resist layer 25 may be, for example, a solder resist layer. A material for the first resist layer 25 may be a material having a lower degree of solder wettability than the first conductor layer 24. Examples of materials for the first resist layer 25 include a polyimide resin and an epoxy resin.

### (2.4) Second Buildup Layer

The second buildup layer 3 is stacked on the second principal surface 12 of the core board 1, the principal surface 412 of the electronic component 41, and the principal surface 812 of the electronic component 8. The second buildup layer 2 includes a plurality of (e.g., two) second dielectric layers 30. If the two second dielectric layers 30 need to be distinguished from each other, then the two second dielectric layers 30 will be hereinafter referred to as a “second dielectric layer 31” and a “second dielectric layer 32,” respectively. In the second buildup layer 3, the second dielectric layer 31 is a second dielectric layer 30 located closest to the second principal surface 12 of the core board 1 in the thickness direction D1 defined for the core board 1. On the other hand, in the second buildup layer 3, the second dielectric layer 32 is a second dielectric layer 30 located most distant from the second principal surface 12 of the core board 1 in the thickness direction D1 defined for the core board 1.

In addition, the second buildup layer 3 further includes a plurality of (e.g., two) second conductor layers 33, 34. The second conductor layer 33 is interposed between the second dielectric layers 31, 32. The second conductor layer 34 is formed on the second dielectric layer 31. These two second conductor layers 33, 34 are formed in one or more predetermined patterns which are defined on a layer-by-layer basis. The second conductor layer 33 includes one or more rewiring portions (conductor portions) P3 as the one or more predetermined patterns. The second conductor layer 34 includes one or more rewiring portions (conductor portions) P4 as the one or more predetermined patterns. In addition, the second buildup layer 3 further includes a plurality of via conductors V3 which connect the second conductor layer 33 and the second conductive layer 103 of the core board 1 to each other and a plurality of via conductors V4 which connect the second conductor layers 34, 33 to each other.

Examples of materials for the plurality of second dielectric layers 30 include an epoxy resin, a phenolic resin, a urethane resin, a silicone resin, and a polyimide resin. A material for the plurality of second conductor layers 33, 34 may include, for example, copper.

The second buildup layer 3 further includes a second resist layer 35. The second resist layer 35 is stacked on the second dielectric layer 32 and the second conductor layer 34. The second resist layer 35 is formed in a predetermined pattern and has a plurality of openings which expose respective parts of the plurality of rewiring portions P4. The second resist layer 35 may be, for example, a solder resist layer. A material for the second resist layer 35 may be a material having a lower degree of solder wettability than the second conductor layer 34. Examples of materials for the second resist layer 35 include a polyimide resin and an epoxy resin.

### (2.5) Electronic Components

As shown in FIG. 1, the plurality of electronic components 6 are arranged on the wiring board 10. More specifically, the plurality of electronic components 6 are arranged on the first buildup layer 2. The electronic components 6 may be, for example, IC chips or surface mount electronic components. Examples of the IC chips include a power amplifier, a low-noise amplifier, a switch, and a controller. Examples of the surface mount electronic components include a chip inductor and a chip capacitor. Examples of the electronic components 6 include a surface acoustic wave filter, a bulk acoustic wave filter, and an LC filter. Optionally, each of the electronic components 6 may also be an electronic component including a plurality of filters.

As used herein, the expression “the electronic components 6 are arranged on the first buildup layer 2” refers to both a situation where the electronic components 6 are mounted on (i.e., mechanically connected to) the first buildup layer 2 and a situation where the electronic components 6 are electrically connected to (appropriate rewiring portions P2 of) the first buildup layer 2. The electronic components 6 are mounted on the principal surface 201 of the first buildup layer 2 by bonding the electronic components 6 to the plurality of rewiring portions P2 of the first buildup layer 2 via a plurality of bonding portions 66, for example. A material for the plurality of bonding portions 66 may be solder, for example. The plurality of bonding portions 66 may be constituent elements of the electronic components 6 or constituent elements interposed between the electronic components 6 and the principal surface 201 of the first buildup layer 2, whichever is appropriate. If the plurality of bonding portions 66 are constituent elements of the electronic components 6, then the plurality of bonding portions 66 are conductive bumps.

The plurality of electronic components 6 includes an electronic component 61. The electronic component 61 may be, for example, a power amplifier. The electronic component 61 is connected to a matching circuit including the electronic component 42 as a circuit element. In other words, the electronic component 42 is a circuit element which forms part of a matching circuit connected to the electronic component 61. The electronic component 61 is electrically connected to at least one of the electrodes 423, 424 of the electronic component 42 via the first conductor layers 23, 24 of the first buildup layer 2. In the RF module 100 according to the first embodiment, the electrode 423 of the electronic component 42 is connected to the electronic component 61 via the first conductor layers 23, 24 and the bonding portions 66. When viewed in plan in the thickness direction D1 defined for the core board 1, the electronic components 61, 42 are preferably located close to each other. In addition, when viewed in plan in the thickness direction D1 defined for the core board 1, at least part of the electronic component 61 and at least part of the electronic component 42 preferably overlap with each other. This allows the wire between the electronic components 61, 42 to be shortened, thus improving the noise immunity of the wire between the electronic component 61 and the matching circuit connected to the electronic component 61. Optionally, the electronic component 61 may be a low-noise amplifier.

The plurality of electronic components 7 are arranged on the wiring board 10. More specifically, the plurality of electronic components 7 are arranged on the second buildup layer 3. The electronic components 7 may be, for example, IC chips or surface mount electronic components. Examples of the IC chips include a power amplifier, a low-noise amplifier, a switch, and a controller. Examples of the surface mount electronic components include a chip inductor and a chip capacitor. The electronic components 7 may each be, for example, a filter, a multiplexer, or a coupler. The filter may be, for example, a surface acoustic wave filter, a bulk acoustic wave filter, or an LC filter. Optionally, each of the electronic components 7 may also be an electronic component including a plurality of filters. As used herein, the expression “the electronic components 7 are arranged on the second buildup layer 3” refers to both a situation where the electronic components 7 are mounted (i.e., mechanically connected) onto the principal surface 301 of the second buildup layer 3 and a situation where the electronic components 7 are electrically connected to (appropriate rewiring portions P4 of) the second buildup layer 3. The electronic components 7 are mounted on the principal surface 301 of the second buildup layer 3 by bonding the electronic components 7 to the plurality of rewiring portions P4 of the second buildup layer 3 via a plurality of bonding portions 76, for example. A material for the plurality of bonding portions 76 may be solder, for example. The plurality of bonding portions 76 may be constituent elements of the electronic components 7 or constituent elements interposed between the electronic components 7 and the principal surface 301 of the second buildup layer 3, whichever is appropriate. If the plurality of bonding portions 76 are constituent elements of the electronic components 7, then the plurality of bonding portions 76 are conductive bumps.

### (2.6) External Connection Terminals

The plurality of external connection terminals 9 are arranged on the second buildup layer 3. As used herein, the expression “the external connection terminals 9 are arranged on the second buildup layer 3” refers to both a situation where the external connection terminals 9 are mechanically connected to the principal surface 301 of the second buildup layer 3 and a situation where the external connection terminals 9 are electrically connected to (appropriate rewiring portions P4 of) the second buildup layer 3. The plurality of external connection terminals 9 includes a ground terminal. The ground terminal may be, for example, a terminal which is electrically connected to a ground electrode of a circuit board included in the communications device to be supplied with a ground potential. The plurality of external connection terminals 9 also includes an antenna terminal connected to an antenna provided outside of the RF module 100, a signal input terminal connected to an input terminal of a power amplifier, and a signal output terminal connected to an output terminal of a low-noise amplifier. A material for the plurality of external connection terminals 9 may be, for example, a metal (such as copper or a copper alloy). Each of the plurality of external connection terminals 9 is a columnar electrode. The columnar electrode may be, for example, a circular columnar electrode. The plurality of external connection terminals 9 may be bonded, via solder, for example, to the rewiring portions P4 of the second buildup layer 3. However, this is only an example and should not be construed as limiting. Alternatively, the plurality of external connection terminals 9 may also be bonded to the rewiring portions P4 via a conductive adhesive (such as conductive paste) or bonded thereto directly, whichever is appropriate. Each of the plurality of external connection terminals 9 has a circular shape when viewed in plan in the thickness direction D1 defined for the core board 1.

### (2.7) First Resin Layer

The first resin layer 115 is disposed on the first buildup layer 2. The first resin layer 115 covers the plurality of electronic components 6 arranged on the first buildup layer 2. The first resin layer 115 contains a resin (such as an epoxy resin). The first resin layer 115 may contain not only the resin but also a filler as well.

### (2.8) Second Resin Layer

The second resin layer 116 covers the plurality of electronic components 7 arranged on the second buildup layer 3. The second resin layer 116 also covers the side surfaces of the plurality of external connection terminals 9. Nevertheless, the second resin layer 116 does not cover the end face 90, facing away from the second buildup layer 3, of the plurality of external connection terminals 9. The second resin layer 116 contains a resin (such as an epoxy resin). The second resin layer 116 may contain not only the resin but also a filler as well. A material for the second resin layer 116 may be the same as, or different from, the material for the first resin layer 115, whichever is appropriate.

### (3) Advantages

In the RF module 100 according to the first embodiment, the electronic components 41, 42 are disposed at least partially inside the through hole 14 of the core board 1. This enables reducing the height of the RF module 100 compared to mounting at least one of the electronic components 41, 42 on the wiring board 10. In addition, the RF module 100 according to the first embodiment may reduce the number of electronic components arranged on either the principal surface 201 or the principal surface 301 of the wiring board 10, compared to mounting at least one of the electronic components 41, 42 on the wiring board 10. Consequently, this enables reducing the area of the RF module 100 as well.

Also, in the RF module 100 according to the first embodiment, the electronic component 42 is stacked on the electronic component 41 in the thickness direction D1 defined for the core board 1. In addition, the electronic component 42 is in contact with the principal surface 411, facing the electronic components 6, of the electronic component 41. Furthermore, the electronic component 42 is a constituent component of the matching circuit connected to the electronic component 61. This allows the electronic components 61, 42 to be connected to each other via the first buildup layer 2. Consequently, the RF module 100 according to the first embodiment may shorten the wire between the electronic components 61, 42, thus improving the noise immunity of the wire between the electronic component 61 and the matching circuit connected to the electronic component 61.

Furthermore, in the RF module 100 according to the first embodiment, the total thickness H2 of the plurality of electronic components 4 is greater than the thickness H1 of the core board 1 when measured in the thickness direction D1 defined for the core board 1. Even in that case, the RF module 100 according to the first embodiment may still be implemented by covering the principal surface 422 of the electronic component 42 with the first buildup layer 2 and covering the principal surface 412 of the electronic component 41 with the second buildup layer 3. This enables reducing the height of the RF module 100 compared to mounting at least one of the electronic components 41, 42 on the wiring board 10. In addition, the RF module 100 according to the first embodiment may reduce the number of electronic components arranged on either the principal surface 201 or the principal surface 301 of the wiring board 10, compared to mounting at least one of the electronic components 41, 42 on the wiring board 10. Consequently, this enables reducing the area of the RF module 100 as well.

### Second Embodiment

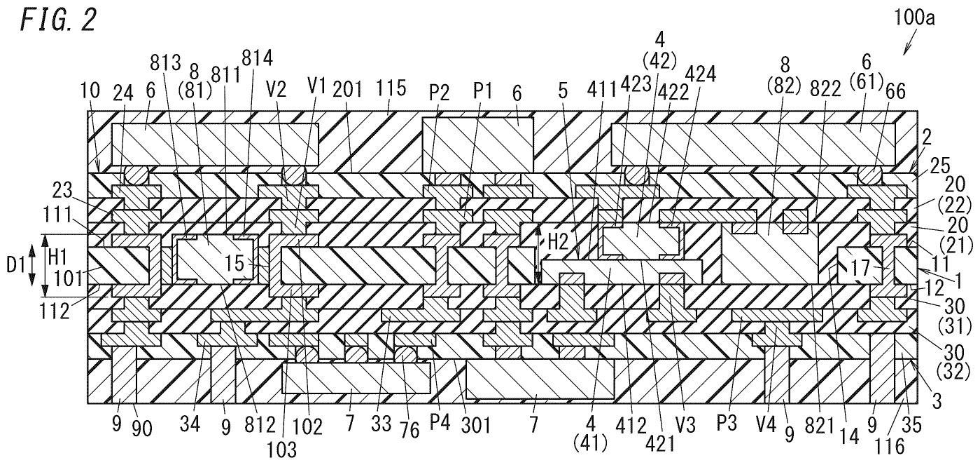

An RF module 100a according to a second embodiment will be described with reference to FIG. 2. In the following description, any constituent element of the RF module 100a, having the same function as a counterpart of the RF module 100 described above, will be designated by the same reference numeral as that counterpart's, and description thereof will be omitted herein.

### (1) Configuration

The RF module 100a according to the second embodiment further includes an electronic component 82 as another constituent component of the matching circuit connected to the electronic component 61.

The electronic component 82 has a pair of principal surfaces 821, 822 facing each other in the thickness direction D1 defined for the core board 1. The electronic component 82 is disposed at least partially inside the through hole 14 of the core board 1. More specifically, as shown in FIG. 2, a part of the electronic component 82 and a part of at least one of the plurality of electronic components 4 are arranged inside the through hole 14.

The electronic component 82 may be, for example, a chip inductor. The electronic components 82, 42 are constituent components of the matching circuit connected to the electronic component 61. The electronic component 82 includes a plurality of electrodes, which form part of the principal surface 822, for example.

The first dielectric layer 20 of the first buildup layer 2 covers the first principal surface 11 of the core board 1, the principal surface 411 of the electronic component 41, the principal surface 422 of the electronic component 42, the principal surface 822 of the electronic component 82, and the principal surface 811 of the electronic component 8 (81). The first conductor layers 23, 24 of the first buildup layer 2 connect the electrode of the electronic component 82 to the electrode of the electronic component 42 and/or the electrode of the electronic component 61. In the RF module 100a according to the second embodiment, the electrode of the electronic component 82 and the electrode 424 of the electronic component 42 are connected to each other via the first conductor layer 23.

The second dielectric layer 30 of the second buildup layer 3 covers the second principal surface 12 of the core board 1, the principal surface 412 of the electronic component 41, the principal surface 821 of the electronic component 82, and the principal surface 812 of the electronic component 81.

### (2) Advantages

In the RF module 100a according to the second embodiment, at least a part of the electronic component 41 and/or at least a part of the electronic component 42 and at least a part of the electronic component 82 are arranged inside the through hole 14 of the core board 1. This enables reducing the height of the RF module 100a compared to mounting at least one of the electronic components 41, 42 or the electronic component 82 on the wiring board 10. In addition, the RF module 100a according to the second embodiment may reduce the number of electronic components arranged on either the principal surface 201 or the principal surface 301 of the wiring board 10, compared to mounting at least one of the electronic components 41, 42 or the electronic component 82 on the wiring board 10. Consequently, this enables reducing the area of the RF module 100a as well.

Also, in the RF module 100a according to the second embodiment, the electronic component 42 is stacked on the electronic component 41 in the thickness direction D1 defined for the core board 1. In addition, the electronic component 42 is in contact with the principal surface 411, facing the electronic component 61, of the electronic component 41. Besides, at least part of the electronic component 82 is disposed inside the through hole 14 of the core board 1. Furthermore, the electronic components 42, 82 are constituent components of the matching circuit connected to the electronic component 61. This allows the electronic components 61, 42 and the electronic component 82 to be connected to each other via the first buildup layer 2. Consequently, the RF module 100a according to the second embodiment may shorten the wire between the electronic components 61, 42 and the electronic component 82, thus improving the noise immunity of the wire between the electronic component 61 and the matching circuit connected to the electronic component 61.

Furthermore, in the RF module 100a according to the second embodiment, the total thickness H2 of the plurality of electronic components 4 is greater than the thickness H1 of the core board 1 when measured in the thickness direction D1 defined for the core board 1. Even in that case, the RF module 100a according to the second embodiment may still be implemented by covering the principal surface 422 of the electronic component 42 with the first buildup layer 2 and covering the principal surface 412 of the electronic component 41 with the second buildup layer 3. This enables reducing the height of the RF module 100a compared to mounting at least one of the electronic components 41, 42 on the wiring board 10. In addition, the RF module 100a according to the second embodiment may reduce the number of electronic components arranged on either the principal surface 201 or the principal surface 301 of the wiring board 10, compared to mounting at least one of the electronic components 41, 42 or the electronic component 82 on the wiring board 10. Consequently, this enables reducing the area of the RF module 100a as well.

### Third Embodiment

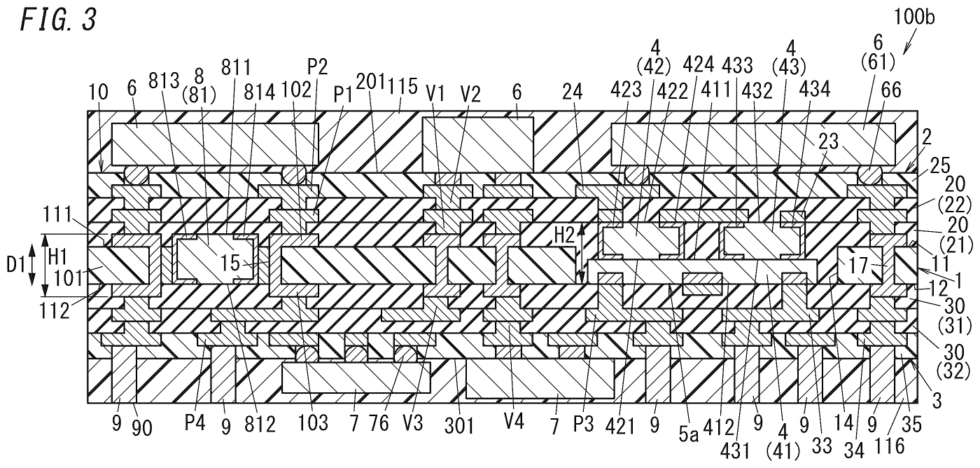

An RF module 100b according to a third embodiment will be described with reference to FIG. 3. In the following description, any constituent element of the RF module 100b, having the same function as a counterpart of the RF module 100 described above, will be designated by the same reference numeral as that counterpart's, and description thereof will be omitted herein.

### (1) Configuration

In the RF module 100b according to the third embodiment, the plurality of electronic component 4 further includes an electronic component 43 as another constituent component of the matching circuit connected to the electronic component 61.

The plurality of electronic components 4 includes not only the electronic components 41, 42 but also the electronic component 43 as well. As shown in FIG. 3, the electronic components 42, 43 are stacked on the electronic component 41 in the thickness direction D1 defined for the core board 1. That is to say, the electronic components 42, 43 are stacked on one side, where the electronic component 61 is located, of the electronic component 41. More specifically, the electronic component 41 has the principal surfaces 411, 412 facing each other in the thickness direction D1 defined for the core board 1. The electronic component 42 has the principal surfaces 421, 422 facing each other in the thickness direction D1 defined for the core board 1. The electronic component 43 has principal surfaces 431, 432 facing each other in the thickness direction D1 defined for the core board 1. The principal surface 411 of the electronic component 41 is in contact with both the principal surface 421 of the electronic component 42 and the principal surface 431 of the electronic component 43. At least one of the plurality of electronic components 4 is disposed at least partially inside the through hole 14 of the core board 1. At least part of an electronic component region 5a to be physically occupied by the electronic components 41, 42, and 43 is present inside the through hole 14 of the core board 1. Thus, at least one of the electronic components 41, 42, and 43 is disposed inside the through hole 14 of the core board 1 either partially or entirely. Note that the total thickness H2 of the plurality of electronic components 4 is the longer one of the distance between the principal surface 412 of the electronic component 41 and the principal surface 422 of the electronic component 42 as measured in the thickness direction D1 defined for the core board 1 or the distance between the principal surface 412 of the electronic component 41 and the principal surface 432 of the electronic component 43 as measured in the thickness direction D1 defined for the core board 1.

The electronic component 43 may be, for example, a chip capacitor. The electronic component 43 includes electrodes 433, 434. At least one of the electrodes 433, 434 of the electronic component 43 is connected to at least one of the electronic components 42, 61 via the first buildup layer 2. In the RF module 100b according to the third embodiment, the electrode 433 of the electronic component 43 is connected to the electrode 424 of the electronic component 42 via the first conductor layer 23 as shown in FIG. 3. Both the electronic components 42, 43 are constituent components of the matching circuit connected to the electronic component 61.

The first dielectric layer 20 of the first buildup layer 2 covers the first principal surface 11 of the core board 1, the principal surface 411 of the electronic component 41, the principal surface 422 of the electronic component 42, the principal surface 432 of the electronic component 43, and the principal surface 811 of the electronic component 8.

The second dielectric layer 30 of the second buildup layer 3 covers the second principal surface 12 of the core board 1, the principal surface 412 of the electronic component 41, and the principal surface 812 of the electronic component 8.

### (2) Advantages

In the RF module 100b according to the third embodiment, at least one of respective parts of the electronic components 41, 42 and 43 are arranged inside the through hole 14 of the core board 1. This enables reducing the height of the RF module 100b compared to mounting at least one of the electronic components 41, 42, and 43 on the wiring board 10. In addition, the RF module 100b according to the third embodiment may reduce the number of electronic components arranged on either the principal surface 201 or the principal surface 301 of the wiring board 10, compared to mounting at least one of the electronic components 41, 42 or 43 on the wiring board 10. Consequently, this enables reducing the area of the RF module 100b as well.

Also, in the RF module 100b according to the third embodiment, the electronic components 42, 43 are stacked on the electronic component 41 in the thickness direction D1 defined for the core board 1. In addition, the electronic components 42, 43 are in contact with the principal surface 411, facing the electronic component 61, of the electronic component 41. Furthermore, the electronic components 42, 43 are constituent components of the matching circuit connected to the electronic component 61. This allows the electronic components 61, 42 and the electronic component 43 to be connected to each other via the first buildup layer 2. Consequently, the RF module 100b according to the third embodiment may shorten the wire between the electronic components 61, 42 and the electronic component 43, thus improving the noise immunity of the wire between the electronic component 61 and the matching circuit connected to the electronic component 61.

Furthermore, in the RF module 100b according to the third embodiment, the total thickness H2 of the plurality of electronic components 4 is greater than the thickness H1 of the core board 1 when measured in the thickness direction D1 defined for the core board 1. That is to say, in the RF module 100b according to the third embodiment, the distance between the principal surface 412 of the electronic component 41 and the principal surface 422 of the electronic component 42 is greater than the thickness H1 of the core board 1. Alternatively, in the RF module 100b according to the third embodiment, the distance between the principal surface 412 of the electronic component 41 and the principal surface 432 of the electronic component 43 is greater than the thickness H1 of the core board 1. Even in that case, the RF module 100b according to the third embodiment may still be implemented by covering the principal surface 422 of the electronic component 42 and the principal surface 432 of the electronic component 43 with the first buildup layer 2 and covering the principal surface 412 of the electronic component 41 with the second buildup layer 3. This enables reducing the height of the RF module 100b compared to mounting at least one of the electronic components 41, 42, and 43 on the wiring board 10. In addition, the RF module 100b according to the third embodiment may reduce the number of electronic components arranged on either the principal surface 201 or the principal surface 301 of the wiring board 10, compared to mounting at least one of the electronic components 41, 42, and 43 on the wiring board 10. Consequently, this enables reducing the area of the RF module 100b as well.

### Fourth Embodiment

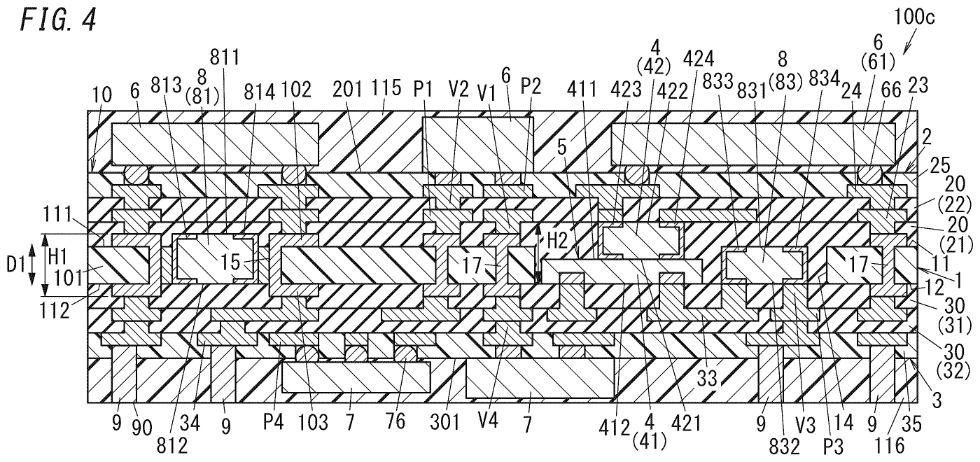

An RF module 100c according to a fourth embodiment will be described with reference to FIG. 4. In the following description, any constituent element of the RF module 100c, having the same function as a counterpart of the RF module 100 described above, will be designated by the same reference numeral as that counterpart's, and description thereof will be omitted herein.

### (1) Configuration

The RF module 100c according to the fourth embodiment further includes an electronic component 83 as another constituent component of the matching circuit connected to the electronic component 41.

The electronic component 83 has a pair of principal surfaces 831, 832 facing each other in the thickness direction D1 defined for the core board 1. The electronic component 83 is disposed at least partially inside the through hole 14 of the core board 1. More specifically, as shown in FIG. 4, a part of the electronic component 83 and respective parts of the electronic components 41, 42 are arranged inside the same through hole 14.

The electronic component 41 is an electronic component connected to the matching circuit. The electronic component 41 may be, for example, a low-noise amplifier. However, this is only an example and should not be construed as limiting. The electronic component 41 does not have to be a low-noise amplifier but may also be a power amplifier, for example.

The electronic component 83 may be, for example, a chip capacitor. The electronic component 83 includes electrodes 833, 834. At least one of the electrodes 833, 834 of the electronic component 83 is connected to the electronic component 41 via the second buildup layer 3. In the RF module 100c according to the fourth embodiment, the electrode 833 of the electronic component 83 is connected to the electronic component 41 via the second conductor layer 33 as shown in FIG. 4. The electronic component 83 serves as a circuit element of the matching circuit connected to the electronic component 41.

The first dielectric layer 20 of the first buildup layer 2 covers the first principal surface 11 of the core board 1, the principal surface 411 of the electronic component 41, the principal surface 422 of the electronic component 42, the principal surface 811 of the electronic component 8 (81), and the principal surface 831 of the electronic component 83.

The second dielectric layer 30 of the second buildup layer 3 covers the second principal surface 12 of the core board 1, the principal surface 412 of the electronic component 41, the principal surface 812 of the electronic component 81, and the principal surface 832 of the electronic component 83.

### (2) Advantages

In the RF module 100c according to the fourth embodiment, at least a part of the electronic component 41 and/or at least a part of the electronic component 42 and at least a part of the electronic component 83 are arranged inside the through hole 14 of the core board 1. This enables reducing the height of the RF module 100b compared to mounting at least one of the electronic components 41, 42, or the electronic component 83 on the wiring board 10. In addition, the RF module 100c according to the fourth embodiment may reduce the number of electronic components arranged on either the principal surface 201 or the principal surface 301 of the wiring board 10, compared to mounting at least one of the electronic components 41, 42 or the electronic component 83 on the wiring board 10. Consequently, this enables reducing the area of the RF module 100c as well.

Also, in the RF module 100c according to the fourth embodiment, the electronic component 42 is stacked on the electronic component 41 in the thickness direction D1 defined for the core board 1. In addition, the electronic component 83 is disposed at least partially inside the through hole 14 of the core board 1. Furthermore, the electronic component 83 is a constituent component of the matching circuit connected to the electronic component 41. Consequently, the RF module 100c according to the fourth embodiment may shorten the wire between the electronic components 41, 83, thus improving the noise immunity of the wire between the electronic component 41 and the matching circuit connected to the electronic component 41.

In addition, in the RF module 100c according to the fourth embodiment, the electronic component 42 is a constituent component of the matching circuit connected to the electronic component 61. This allows the electronic components 61, 42 to be connected to each other via the first buildup layer 2. Consequently, the RF module 100c according to the fourth embodiment may shorten the wire between the electronic components 61, 42, thus improving the noise immunity of the wire between the electronic component 61 and the matching circuit connected to the electronic component 61.

Furthermore, in the RF module 100c according to the fourth embodiment, the total thickness H2 of the plurality of electronic components 4 is greater than the thickness H1 of the core board 1 when measured in the thickness direction D1 defined for the core board 1. Even in that case, the RF module 100c according to the fourth embodiment may still be implemented by covering the principal surface 422 of the electronic component 42 with the first buildup layer 2 and covering the principal surface 412 of the electronic component 41 with the second buildup layer 3. This enables reducing the height of the RF module 100c compared to mounting at least one of the electronic components 41, 42 on the wiring board 10. In addition, the RF module 100c according to the fourth embodiment may reduce the number of electronic components arranged on either the principal surface 201 or the principal surface 301 of the wiring board 10, compared to mounting at least one of the electronic components 41, 42 or the electronic component 83 on the wiring board 10. Consequently, this enables reducing the area of the RF module 100c as well.

### Fifth Embodiment

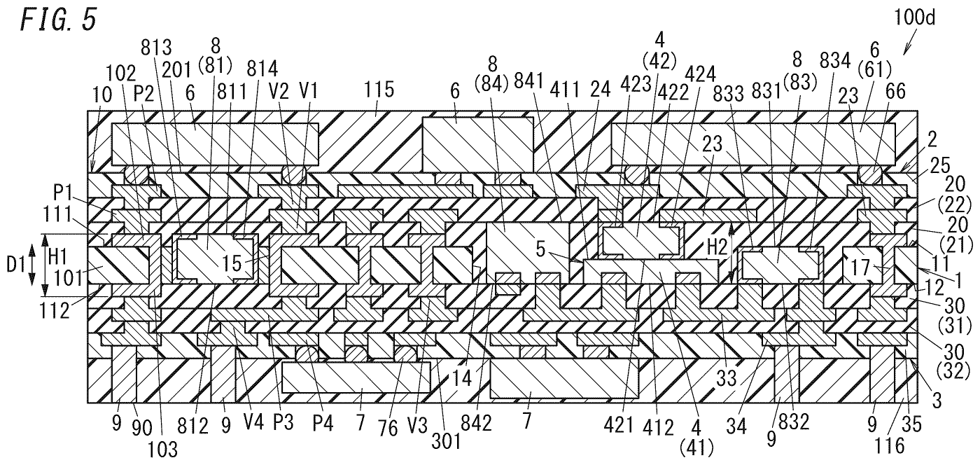

An RF module 100d according to a fifth embodiment will be described with reference to FIG. 5. In the following description, any constituent element of the RF module 100d, having the same function as a counterpart of the RF module 100c described above, will be designated by the same reference numeral as that counterpart's, and description thereof will be omitted herein.

### (1) Configuration

The RF module 100d according to the fifth embodiment further includes an electronic component 84 as another constituent component of the matching circuit connected to the electronic component 41.

The electronic component 84 has a pair of principal surfaces 841, 842 facing each other in the thickness direction D1 defined for the core board 1. The electronic component 84 is disposed at least partially inside the through hole 14 of the core board 1. More specifically, as shown in FIG. 5, a part of the electronic component 84, respective parts of the electronic components 41, 42, and a part of the electronic component 83 are arranged inside the same through hole 14.

The electronic component 84 may be, for example, a chip inductor. The electronic component 84 includes a plurality of electrodes. The plurality of electrodes forms part of the principal surface 842, for example. The electrodes of the electronic component 84 are connected to at least one of the electronic components 41, 83 via the second buildup layer 3. In the RF module 100d according to the fifth embodiment, the electronic component 84 is connected to the electronic component 41 via the second conductor layer 33 as shown in FIG. 5. The electronic component 84 is a constituent component of the matching circuit connected to the electronic component 41.

The principal surface 842 of the electronic component 84 and the principal surface 412 of the electronic component 41 may be flush with each other. As used herein, the expression “the principal surface 842 of the electronic component 84 and the principal surface 412 of the electronic component 41 are flush with each other” may also refer to a situation where a difference is caused by providing a rewiring layer in contact with both the principal surface 842 of the electronic component 84 and the principal surface 412 of the electronic component 41 for the second dielectric layer 31. This allows the electronic component 84 and the electronic component 41 to be connected to each other via the rewiring layer.

The first dielectric layer 20 of the first buildup layer 2 covers the first principal surface 11 of the core board 1, the principal surface 411 of the electronic component 41, the principal surface 422 of the electronic component 42, the principal surface 811 of the electronic component 8 (81), the principal surface 831 of the electronic component 83, and the principal surface 841 of the electronic component 84.

The second dielectric layer 30 of the second buildup layer 3 covers the second principal surface 12 of the core board 1, the principal surface 412 of the electronic component 41, the principal surface 812 of the electronic component 81, the principal surface 832 of the electronic component 83, and the principal surface 842 of the electronic component 84.

### (2) Advantages

In the RF module 100d according to the fifth embodiment, at least a part of the electronic component 41 and/or at least a part of the electronic component 42, at least a part of the electronic component 83, and at least a part of the electronic component 84 are arranged inside the through hole 14 of the core board 1. Thus, the RF module 100d according to the fifth embodiment may reduce the height of the RF module 100b compared to mounting at least one of the electronic components 41, 42, the electronic component 83, or the electronic component 84 on the wiring board 10. In addition, the RF module 100d according to the fifth embodiment may reduce the number of electronic components arranged on either the principal surface 201 or the principal surface 301 of the wiring board 10, compared to mounting at least one of the electronic components 41, 42, the electronic component 83, or the electronic component 84 on the wiring board 10. Consequently, this enables reducing the area of the RF module 100d as well.

Also, in the RF module 100d according to the fifth embodiment, the electronic component 42 is stacked on the electronic component 41 in the thickness direction D1 defined for the core board 1. In addition, each of the electronic components 83, 84 is disposed at least partially inside the through hole 14 of the core board 1. Furthermore, the electronic components 83, 84 are constituent components of the matching circuit connected to the electronic component 41. Consequently, the RF module 100d according to the fifth embodiment may shorten the wire between the electronic components 41, 83 and the electronic component 84, thus improving the noise immunity of the wire between the electronic component 41 and the matching circuit connected to the electronic component 41.

Besides, in the RF module 100d according to the fifth embodiment, the electronic component 42 is a constituent component of the matching circuit connected to the electronic component 61. This allows the electronic components 61, 42 to be connected to each other via the first buildup layer 2. Consequently, the RF module 100d according to the fifth embodiment may shorten the wire between the electronic components 61, 42, thus improving the noise immunity of the wire between the electronic component 61 and the matching circuit connected to the electronic component 61.

Furthermore, in the RF module 100d according to the fifth embodiment, the total thickness H2 of the plurality of electronic components 4 is greater than the thickness H1 of the core board 1 when measured in the thickness direction D1 defined for the core board 1. Even in that case, the RF module 100d according to the fifth embodiment may still be implemented by covering the principal surface 422 of the electronic component 42 with the first buildup layer 2 and covering the principal surface 412 of the electronic component 41 with the second buildup layer 3. This enables reducing the height of the RF module 100d compared to mounting at least one of the electronic components 41, 42, the electronic component 83, or the electronic component 84 on the wiring board 10. In addition, the RF module 100d according to the fifth embodiment may reduce the number of electronic components arranged on either the principal surface 201 or the principal surface 301 of the wiring board 10, compared to mounting at least one of the electronic components 41, 42, the electronic component 83, or the electronic component 84 on the wiring board 10. Consequently, this enables reducing the area of the RF module 100d as well.

### Sixth Embodiment

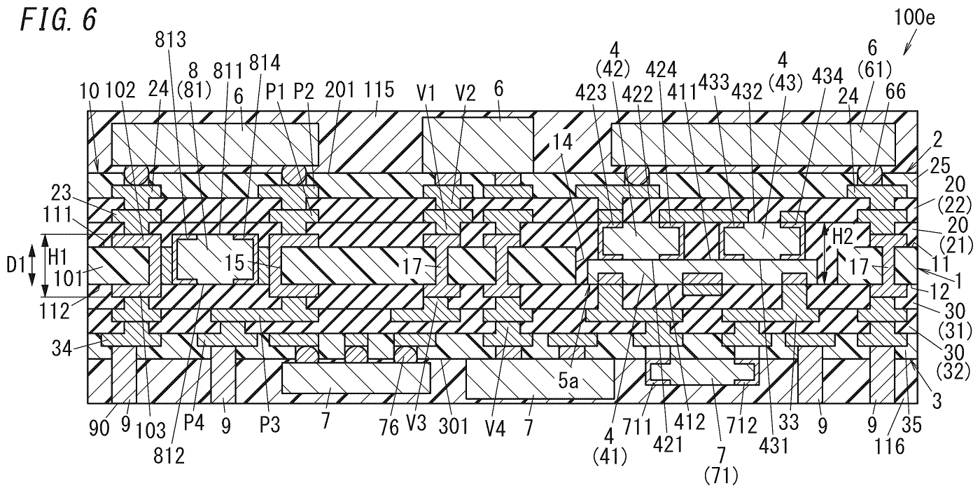

An RF module 100e according to a sixth embodiment will be described with reference to FIG. 6. In the following description, any constituent element of the RF module 100e, having the same function as a counterpart of the RF module 100c described above, will be designated by the same reference numeral as that counterpart's, and description thereof will be omitted herein.

### (1) Configuration

The RF module 100e according to the sixth embodiment further includes an electronic component 71 as another constituent component of the matching circuit connected to the electronic component 41. In addition, in the RF module 100e according to the sixth embodiment, the plurality of electronic components 4 further includes an electronic component 43 as another constituent component of the matching circuit connected to the electronic component 61.

The electronic component 71 is mounted on the principal surface 301 of the second buildup layer 3. The electronic component 71 may be, for example, a chip capacitor. The electronic component 71 includes electrodes 711, 712. At least one of the electrodes 711, 712 of the electronic component 71 is connected to the electronic component 41 via the second buildup layer 3. In the RF module 100e according to the sixth embodiment, the electrodes 711, 712 of the electronic component 71 are connected to the electronic component 41 via the second conductor layers 33, 34 as shown in FIG. 6. The electronic component 71 serves as a circuit element of the matching circuit connected to the electronic component 41.

When viewed in plan in the thickness direction D1 defined for the core board 1, the electronic components 41, 71 are preferably located close to each other. In addition, when viewed in plan in the thickness direction D1 defined for the core board 1, at least part of the electronic component 41 and at least part of the electronic component 71 preferably overlap with each other. This allows the wire between the electronic components 71, 41 to be shortened.

The plurality of electronic components 4 includes not only the electronic components 41, 42 but also the electronic component 43 as well. As shown in FIG. 6, the electronic components 42, 43 are stacked on the electronic component 41 in the thickness direction D1 defined for the core board 1. More specifically, the electronic component 41 has the principal surfaces 411, 412 facing each other in the thickness direction D1 defined for the core board 1. The electronic component 42 has the principal surfaces 421, 422 facing each other in the thickness direction D1 defined for the core board 1. The electronic component 43 has principal surfaces 431, 432 facing each other in the thickness direction D1 defined for the core board 1. The principal surface 411 of the electronic component 41 is in contact with both the principal surface 421 of the electronic component 42 and the principal surface 431 of the electronic component 43. At least part of an electronic component region 5a occupied by the plurality of electronic components 4 is present inside the through hole 14 of the core board 1. Thus, at least one of the electronic components 41, 42, and 43 is disposed inside the through hole 14 of the core board 1 either partially or entirely.

The electronic component 43 may be, for example, a chip capacitor. The electronic component 43 includes electrodes 433, 434. At least one of the electrodes 433, 434 of the electronic component 43 is connected to at least one of the electronic components 42, 61 via the first buildup layer 2. In the RF module 100e according to the sixth embodiment, the electrode 433 of the electronic component 43 is connected to the electrode 424 of the electronic component 42 via the first conductor layer 23 as shown in FIG. 6. Both the electronic components 42, 43 are constituent components of the matching circuit connected to the electronic component 61.

The first dielectric layer 21 of the first buildup layer 2 covers the first principal surface 11 of the core board 1, the principal surface 411 of the electronic component 41, the principal surface 422 of the electronic component 42, the principal surface 432 of the electronic component 43, and the principal surface 811 of the electronic component 8.

The second dielectric layer 31 of the second buildup layer 3 covers the second principal surface 12 of the core board 1, the principal surface 412 of the electronic component 41, and the principal surface 812 of the electronic component 8.

### (2) Advantages

In the RF module 100e according to the sixth embodiment, at least one of respective parts of the electronic components 41, 42 and 43 are arranged inside the through hole 14 of the core board 1. Thus, the RF module 100e according to the sixth embodiment may reduce the height of the RF module 100e compared to mounting at least one of the electronic components 41, 42, and 43 on the wiring board 10. In addition, the RF module 100e according to the sixth embodiment may reduce the number of electronic components arranged on either the principal surface 201 or the principal surface 301 of the wiring board 10, compared to mounting at least one of the electronic components 41, 42 or 43 on the wiring board 10. Consequently, this enables reducing the area of the RF module 100e as well.

Also, in the RF module 100e according to the sixth embodiment, the electronic components 42, 43 are stacked on the electronic component 41 in the thickness direction D1 defined for the core board 1. In addition, in the RF module 100e according to the sixth embodiment, the electronic components 42, 43 are in contact with the principal surface 411, facing the electronic component 61, of the electronic component 41. Furthermore, the electronic component 71 is a constituent component of the matching circuit connected to the electronic component 41. This allows the electronic components 41, 71 to be connected to each other via the second buildup layer 3. Consequently, the RF module 100e according to the sixth embodiment may shorten the wire between the electronic components 41, 71, thus improving the noise immunity of the wire between the electronic component 41 and the matching circuit connected to the electronic component 41.

Furthermore, in the RF module 100e according to the sixth embodiment, the electronic components 42, 43 are constituent components of the matching circuit connected to the electronic component 61. This allows the electronic components 61, 42, and 43 to be connected to each other via the first buildup layer 2. Consequently, the RF module 100e according to the sixth embodiment may shorten the wire between the electronic component 61 and the electronic components 42, 43, thus improving the noise immunity of the wire between the electronic component 61 and the matching circuit connected to the electronic component 61.

Furthermore, in the RF module 100e according to the sixth embodiment, the total thickness H2 of the plurality of electronic components 4 is greater than the thickness H1 of the core board 1 when measured in the thickness direction D1 defined for the core board 1. That is to say, in the RF module 100e according to the sixth embodiment, the distance between the principal surface 412 of the electronic component 41 and the principal surface 422 of the electronic component 42 is greater than the thickness H1 of the core board 1. Alternatively, in the RF module 100e according to the sixth embodiment, the distance between the principal surface 412 of the electronic component 41 and the principal surface 432 of the electronic component 43 is greater than the thickness H1 of the core board 1. Even in that case, the RF module 100e according to the sixth embodiment may still be implemented by covering the principal surface 422 of the electronic component 42 and the principal surface 432 of the electronic component 43 with the first buildup layer 2 and covering the principal surface 412 of the electronic component 41 with the second buildup layer 3. Thus, the RF module 100e according to the sixth embodiment may reduce the height of the RF module 100e compared to mounting at least one of the electronic components 41, 42, and 43 on the wiring board 10. In addition, the RF module 100e according to the sixth embodiment may reduce the number of electronic components arranged on either the principal surface 201 or the principal surface 301 of the wiring board 10, compared to mounting at least one of the electronic components 41, 42, and 43 on the wiring board 10. Consequently, this enables reducing the area of the RF module 100e as well.

### (Variations)

Note that the first to sixth embodiments described above are only exemplary ones of various embodiments of the present disclosure and should not be construed as limiting. Rather, the first to sixth embodiments may be readily modified in various manners depending on a design choice or any other factor without departing from the scope of the present disclosure. Optionally, multiple different constituent elements of mutually different embodiments may be adopted in combination as appropriate.

For example, the core board 1 does not have to be a double-sided printed wiring board but may also be a low temperature co-fired ceramic board, for example.

Also, in the RF modules 100, 100a, 100b, 100c, 100d, 100e, each of the plurality of external connection terminals 9 may also be a ball bump with electrical conductivity. Examples of materials for the ball bump serving as each of the plurality of external connection terminals 9 include gold, copper, and solder.

The RF modules 100, 100a, 100b, 100c, 100d each include electronic components 7 mounted on the principal surface 301 of the second buildup layer 3. However, this is only an example and should not be construed as limiting. Alternatively, the RF modules 100, 100a, 100b, 100c, 100d may each be configured such that the electronic components 7 are disposed on the principal surface 201 of the first buildup layer 2 with no electronic components 7 mounted on the principal surface 301 of the second buildup layer 3.

Furthermore, in the RF modules 100, 100a, 100b, 100c, 100d, 100e, the electronic components 6 need to include at least the electronic component 61.

Furthermore, in the RF module 100e, the electronic components 7 need to include at least the electronic component 71.

The RF modules 100, 100a, 100b, 100c, 100d each include the electronic component 8 disposed inside the second through hole 15 of the core board 1. However, this is only an example and should not be construed as limiting. For example, the core board 1 may have no second through hole 15 and the electronic component 8 may be mounted on either the principal surface 201 of the first buildup layer 2 or the principal surface 301 of the second buildup layer 3.

Furthermore, in the RF modules 100, 100a, 100b, 100c, 100d, 100e, the electronic component 42 is a chip capacitor serving as a circuit component of a matching circuit connected to the electronic component 61. Also, in the RF modules 100c and 100e, the electronic component 43 is a chip capacitor serving as a circuit component of a matching circuit connected to the electronic component 61. Alternatively, either the electronic component 42 or the electronic component 43 may also be a chip inductor serving as a circuit component of a matching circuit connected to the electronic component 61. Still alternatively, either the electronic component 42 or the electronic component 43 may also be, for example, a decoupling capacitor, a coupling capacitor, or a bypass capacitor, not as a part of a matching circuit connected to the electronic component 61. Likewise, in the RF modules 100c, 100d, and 100e, the electronic component 71 is a chip capacitor serving as a circuit component of a matching circuit connected to the electronic component 41. Alternatively, the electronic component 71 may also be a chip inductor serving as a circuit component of a matching circuit connected to the electronic component 41. Still alternatively, the electronic component 71 may also be, for example, a decoupling capacitor, a coupling capacitor, or a bypass capacitor, not as a part of a matching circuit connected to the electronic component 41.

Furthermore, in the RF modules 100b, 100e, the electronic components 42, 43 are stacked on the electronic component 41. However, this is only an example and should not be construed as limiting. Alternatively, three or more electronic components may be stacked on the principal surface 411, facing the first buildup layer 2, of the electronic component 41. Furthermore, if a plurality of electronic components are stacked on the principal surface 411 of the electronic component 41, all of those electronic components may be elements which form part of a matching circuit connected to the electronic component 61. Alternatively, only some of the electronic components may be elements which form part of the matching circuit for the electronic component 61.

Furthermore, in the RF modules 100, 100a, 100b, 100c, 100d, 100e, the principal surface 411 of the electronic component 41 and the principal surface 421 of the electronic component 42 are in contact with each other. Also, in the RF modules 100b, 100e, the principal surface 411 of the electronic component 41 and the principal surface 431 of the electronic component 43 are in contact with each other. Nevertheless, in the plurality of electronic components 4 stacked in the thickness direction D1 defined for the core board 1, their principal surfaces do not have to be in contact with each other. For example, either a resin layer or an adhesive layer may be interposed between the principal surface 411 of the electronic component 41 and the principal surface 421 of the electronic component 42.

Furthermore, in the RF modules 100c, 100d, 100e, the electronic components 42 and 43 are constituent elements of the matching circuit connected to the electronic component 61. However, this is only an example and should not be construed as limiting. Alternatively, for example, the electronic components 42 and 43 may also be elements which are not directly connected to the electronic component 61. Even in that case, the advantages of shortening the wire between the electronic component 41 and the matching circuit connected to the electronic component 41 and thereby improving its noise immunity are also achieved.

### (Aspects)

The foregoing description of embodiments provides specific implementations of the following aspects of the present disclosure.

A radio frequency module (100-100e) according to a first aspect includes a wiring board (10), a first electronic component (41) and a second electronic component (42), and a third electronic component (61). The first electronic component (41) and the second electronic component (42) are built in the wiring board (10). The third electronic component (61) is disposed on the wiring board (10) and connected to a matching circuit. The wiring board (10) includes a core board (1), a first buildup layer (2), and a second buildup layer (3). The core board (1) has not only a first principal surface (11) and a second principal surface (12) facing each other but also a through hole (14). The first buildup layer (2) is stacked on the first principal surface (11) of the core board (1). The second buildup layer (3) is stacked on the second principal surface (12) of the core board (1). At least one of the first electronic component (41) or the second electronic component (42) is disposed at least partially inside the through hole (14) of the core board (1). The third electronic component (61) is disposed on the first buildup layer (2). The second electronic component (42) is stacked on one side, where the third electronic component (61) is located, of the first electronic component (41) in a thickness direction (D1) defined for the core board (1). The second electronic component (42) is a constituent component of the matching circuit.

The radio frequency module (100-100e) according to this aspect may have a reduced thickness as measured in the thickness direction (D1) defined for the core board (1), compared to providing either the first electronic component (41) or the second electronic component (42) on either the first buildup layer (2) or the second buildup layer (3). In addition, this may also shorten the wire between the second electronic component (42) and the third electronic component (61), thus improving the noise immunity of the wire between the third electronic component (61) and the matching circuit connected to the third electronic component (61).

In a radio frequency module (100-100e) according to a second aspect, which may be implemented in conjunction with the first aspect, when measured in the thickness direction (D1) defined for the core board (1), a total thickness (H2) of the first electronic component (41) and the second electronic component (42) is greater than a thickness (H1) of the core board (1).

The radio frequency module (100-100e) according to this aspect may have a reduced thickness as measured in the thickness direction (D1) defined for the core board (1), compared to providing either the first electronic component (41) or the second electronic component (42) on either the first buildup layer (2) or the second buildup layer (3).

In a radio frequency module (100-100e) according to a third aspect, which may be implemented in conjunction with the first or second aspect, the second electronic component (42) is a capacitor.

The radio frequency module (100-100e) according to this aspect may have a reduced thickness as measured in the thickness direction (D1) defined for the core board (1) when the matching circuit connected to the third electronic component (61) includes a capacitor.

A radio frequency module (100a) according to a fourth aspect, which may be implemented in conjunction with any one of the first to third aspects, further includes a fourth electronic component (82). The fourth electronic component (82) is built in the wiring board (10). The fourth electronic component (82) is an inductor and is disposed at least partially inside the through hole (14) of the core board (1). The second electronic component (42) and the fourth electronic component (82) are constituent components of the matching circuit.

The radio frequency module (100a) according to this aspect may prevent, when the matching circuit connected to the third electronic component (61) includes an inductor, the inductor from causing an increase in the thickness of the radio frequency module (100a) as measured in the thickness direction (D1) defined for the core board (1). In addition, disposing the fourth electronic component (82), which is implemented as an inductor, in the vicinity of the third electronic component (61) allows the wire between the third electronic component (61) and the matching circuit to be shortened. This may improve the noise immunity of the wire between the third electronic component (61) and the matching circuit connected to the third electronic component (61).

A radio frequency module (100b; 100e) according to a fifth aspect, which may be implemented in conjunction with any one of the first to third aspects, further includes a fourth electronic component (43). The fourth electronic component (43) is built in the wiring board (10). The fourth electronic component (43) is a capacitor. The fourth electronic component (43) is stacked on one side, where the third electronic component (61) is located, of the first electronic component (41) in the thickness direction (D1) defined for the core board (1). The second electronic component (42) and the fourth electronic component (43) are constituent components of the matching circuit.

The radio frequency module (100b; 100e) according to this aspect may prevent, when the matching circuit connected to the third electronic component (61) includes a plurality of capacitors, the capacitors from causing an increase in the thickness of the radio frequency module (100b; 100e) as measured in the thickness direction (D1) defined for the core board (1). In addition, arranging the second electronic component (42) and the fourth electronic component (43), which are included in the matching circuit, close to each other allows the wire between the third electronic component (61) and the matching circuit to be shortened. This may improve the noise immunity of the wire between the third electronic component (61) and the matching circuit connected to the third electronic component (61).

In a radio frequency module (100-100e) according to a sixth aspect, which may be implemented in conjunction with any one of the first to fifth aspects, the third electronic component (61) includes either a power amplifier or a low-noise amplifier.

The radio frequency module (100-100e) according to this aspect may reduce the height of the radio frequency module (100-100e) serving as a transmission module, a reception module, or a transmission/reception module, of which the wire between the third electronic component (61) and the matching circuit connected to the third electronic component (61) has excellent noise immunity.

A radio frequency module (100c; 100d; 100e) according to a seventh aspect includes a wiring board (10), a first electronic component (41) and a second electronic component (42), and an external connection terminal (9). The first electronic component (41) and the second electronic component (42) are built in the wiring board (10). The external connection terminal (9) is disposed on the wiring board (10). The wiring board (10) includes a core board (1), a first buildup layer (2), and a second buildup layer (3). The core board (1) has not only a first principal surface (11) and a second principal surface (12) facing each other but also a through hole (14). The first buildup layer (2) is stacked on the first principal surface (11) of the core board (1). The second buildup layer (3) is stacked on the second principal surface (12) of the core board (1). At least one of the first electronic component (41) or the second electronic component (42) is disposed at least partially inside the through hole (14) of the core board (1). The external connection terminal (9) is disposed on the second buildup layer (3). The second electronic component (42) is stacked on one side, opposite from another side where the external connection terminal (9) is located, of the first electronic component (41) in a thickness direction (D1) defined for the core board (1). The first electronic component (41) is an IC chip connected to the matching circuit.

The radio frequency module (100c; 100d; 100e) according to this aspect may have a reduced thickness as measured in the thickness direction (D1) defined for the core board (1), compared to providing either the first electronic component (41) or the second electronic component (42) on either the first buildup layer (2) or the second buildup layer (3).

In a radio frequency module (100c; 100d; 100e) according to an eighth aspect, which may be implemented in conjunction with the seventh aspect, when measured in the thickness direction (D1) defined for the core board (1), a total thickness (H2) of the first electronic component (41) and the second electronic component (42) is greater than a thickness (H1) of the core board (1).

The radio frequency module (100c; 100d; 100e) according to this aspect may have a reduced thickness as measured in the thickness direction (D1) defined for the core board (1), compared to providing either the first electronic component (41) or the second electronic component (42) on either the first buildup layer (2) or the second buildup layer (3).

A radio frequency module (100c) according to a ninth aspect, which may be implemented in conjunction with the seventh or eighth aspect, further includes a third electronic component (83). The third electronic component (83) is built in the wiring board (10). The third electronic component (83) is disposed at least partially inside the through hole (14) of the core board (1). The third electronic component (83) is a capacitor and is a constituent component of the matching circuit.

The radio frequency module (100c) according to this aspect may have a reduced thickness as measured in the thickness direction (D1) defined for the core board (1) when the matching circuit connected to the first electronic component (41) includes a capacitor. This aspect may also shorten the wire between the first electronic component (41) and the third electronic component (83) implemented as a capacitor, thus improving the noise immunity of the wire between the first electronic component (41) and the third electronic component (83).

A radio frequency module (100d) according to a tenth aspect, which may be implemented in conjunction with the seventh or eighth aspect, further includes a third electronic component (84). The third electronic component (84) is built in the wiring board (10). The third electronic component (84) is disposed at least partially inside the through hole (14) of the core board (1). The third electronic component (84) is an inductor and is a constituent component of the matching circuit.

The radio frequency module (100d) according to this aspect may shorten the wire between the first electronic component (41) and the third electronic component (84) implemented as an inductor when the matching circuit connected to the first electronic component (41) includes the inductor. This may improve the noise immunity of the wire between the first electronic component (41) and the third electronic component (84).

In a radio frequency module (100d) according to an eleventh aspect, which may be implemented in conjunction with the tenth aspect, a principal surface (842), facing the second buildup layer (3), of the third electronic component (84) and a principal surface (412), facing the second buildup layer (3), of the first electronic component (41) are flush with each other.

The radio frequency module (100d) according to this aspect allows a wire to be formed easily, using the second buildup layer (3), between the first electronic component (41) and the third electronic component (84) implemented as an inductor. This may improve the noise immunity of the wire between the first electronic component (41) and the third electronic component (84).

A radio frequency module (100e) according to a twelfth aspect, which may be implemented in conjunction with the seventh or eighth aspect, further includes a third electronic component (71). The third electronic component (71) is disposed on the second buildup layer (3). The third electronic component (71) is a capacitor and is a constituent component of the matching circuit.

The radio frequency module (100e) according to this aspect may shorten the wire between the first electronic component (41) and the third electronic component (71) implemented as a capacitor when the matching circuit connected to the first electronic component (41) includes the capacitor. This may improve the noise immunity of the wire between the first electronic component (41) and the third electronic component (71).

In a radio frequency module (100c-100e) according to a thirteenth aspect, which may be implemented in conjunction with any one of the seventh to twelfth aspects, the first electronic component (41) includes either a power amplifier or a low-noise amplifier.

The radio frequency module (100-100e) according to this aspect may reduce the height of the radio frequency module (100c-100e) serving as a transmission module, a reception module, or a transmission/reception module, of which the wire between the first electronic component (41) and the matching circuit connected to the first electronic component (41) has excellent noise immunity.
1 Core Board
11 First Principal Surface
12 Second Principal Surface
14 First Through Hole (Through Hole)
15 Second Through Hole
17 Feedthrough Via Conductor
101 Dielectric Substrate
111 Principal Surface
112 Principal Surface
102 First Conductive Layer
103 Second Conductive Layer
2 First Buildup Layer
201 Principal Surface
20 First Dielectric Layer
21 First Dielectric Layer
22 First Dielectric Layer
23 First Conductor Layer
24 First Conductor Layer
25 First Resist Layer
3 Second Buildup Layer
301 Principal Surface
30 Second Dielectric Layer
31 Second Dielectric Layer
32 Second Dielectric Layer
33 Second Conductor Layer
34 Second Conductor Layer
35 Second Resist Layer
4 Electronic Component
41 Electronic Component (First Electronic Component)
411 Principal Surface
412 Principal Surface
42 Electronic Component (Second Electronic Component)
421 Principal Surface
422 Principal Surface
423 Electrode
424 Electrode
43 Electronic Component (Fourth Electronic Component)
431 Principal Surface
432 Principal Surface
433 Electrode
434 Electrode
5,5a Electronic Component Region
6 Electronic Component
61 Electronic Component (Third Electronic Component)
66 Bonding Portion
7 Electronic Component
71 Electronic Component (Third Electronic Component)
711 Electrode
712 Electrode
76 Bonding Portion
8 Electronic Component
81 Electronic Component
811 Principal Surface
812 Principal Surface
813 Electrode
814 Electrode
82 Electronic Component (Fourth Electronic Component)
821 Principal Surface
822 Principal Surface
83 Electronic Component (Third Electronic Component)
831 Principal Surface
832 Principal Surface
833 Electrode
834 Electrode
84 Electronic Component (Third Electronic Component)
841 Principal Surface
842 Principal Surface
9 External Connection Terminal
90 End Face
100 Wiring Board
100, 100a, 100b, 100c, 100d, 100e RF Module
115 First Resin Layer
116 Second Resin Layer
D1 Thickness Direction
H1 Thickness of Core Board
H2 Total Thickness of Electronic Components
P1 Rewiring Portion
P2 Rewiring Portion
P3 Rewiring Portion
P4 Rewiring Portion
V1 Via Conductor
V2 Via Conductor
V3 Via Conductor
V4 Via Conductor

1. A radio frequency module comprising:
a wiring board;
a first electronic component and a second electronic component, the first electronic component and the second electronic component being built in the wiring board; and
a third electronic component disposed on the wiring board and connected to a matching circuit,
the wiring board including:
a core board having not only a first principal surface and a second principal surface facing each other but also a through hole;
a first buildup layer stacked on the first principal surface of the core board; and
a second buildup layer stacked on the second principal surface of the core board,
at least one of the first electronic component or the second electronic component being disposed at least partially inside the through hole of the core board,
the third electronic component being disposed on the first buildup layer,
the second electronic component being stacked on a surface of the first electronic component facing to the third electronic component in a thickness direction defined for the core board, and
the second electronic component being a constituent component of the matching circuit.

2. The radio frequency module of claim 1, wherein
when measured in the thickness direction defined for the core board, a total thickness of the first electronic component and the second electronic component is greater than a thickness of the core board.

3. The radio frequency module of claim 1, wherein
the second electronic component is a capacitor.

4. The radio frequency module of claim 1, further comprising a fourth electronic component built in the wiring board, wherein
the fourth electronic component is an inductor and is disposed at least partially inside the through hole of the core board, and
the second electronic component and the fourth electronic component are constituent components of the matching circuit.

5. The radio frequency module of claim 1, further comprising a fourth electronic component built in the wiring board, wherein
the fourth electronic component is a capacitor,
the fourth electronic component is stacked on a surface of the first electronic component facing to the third electronic component in the thickness direction defined for the core board, and
the second electronic component and the fourth electronic component are constituent components of the matching circuit.

6. The radio frequency module of claim 1, wherein
the third electronic component includes either a power amplifier or a low-noise amplifier.

7. A radio frequency module comprising:
a wiring board;
a first electronic component and a second electronic component, the first electronic component and the second electronic component being built in the wiring board; and
an external connection terminal disposed on the wiring board,
the wiring board including:
a core board having not only a first principal surface and a second principal surface facing each other but also a through hole;
a first buildup layer stacked on the first principal surface of the core board; and
a second buildup layer stacked on the second principal surface of the core board,
at least one of the first electronic component or the second electronic component being disposed at least partially inside the through hole of the core board,
the external connection terminal being disposed on the second buildup layer,
the second electronic component being stacked on a surface of the first electronic component opposite to the third electronic component in a thickness direction defined for the core board, and
the first electronic component being an IC chip connected to the matching circuit.

8. The radio frequency module of claim 7, wherein
when measured in the thickness direction defined for the core board, a total thickness of the first electronic component and the second electronic component is greater than a thickness of the core board.

9. The radio frequency module of claim 7, further comprising a third electronic component built in the wiring board, wherein
the third electronic component is disposed at least partially inside the through hole of the core board, and
the third electronic component is a capacitor and is a constituent component of the matching circuit.

10. The radio frequency module of claim 7, further comprising a third electronic component built in the wiring board, wherein
the third electronic component is disposed at least partially inside the through hole of the core board, and
the third electronic component is an inductor and is a constituent component of the matching circuit.

11. The radio frequency module of claim 10, wherein
a principal surface, facing the second buildup layer, of the third electronic component and a principal surface, facing the second buildup layer, of the first electronic component are flush with each other.

12. The radio frequency module of claim 7, further comprising a third electronic component disposed on the second buildup layer, wherein
the third electronic component is a capacitor and is a constituent component of the matching circuit connected to the first electronic component.

13. The radio frequency module of claim 7, wherein
the first electronic component includes either a power amplifier or a low-noise amplifier.

14. The radio frequency module of claim 2, wherein
the second electronic component is a capacitor.

15. The radio frequency module of claim 2, further comprising a fourth electronic component built in the wiring board, wherein
the fourth electronic component is an inductor and is disposed at least partially inside the through hole of the core board, and
the second electronic component and the fourth electronic component are constituent components of the matching circuit.

16. The radio frequency module of claim 3, further comprising a fourth electronic component built in the wiring board, wherein
the fourth electronic component is an inductor and is disposed at least partially inside the through hole of the core board, and
the second electronic component and the fourth electronic component are constituent components of the matching circuit.

17. The radio frequency module of claim 2, further comprising a fourth electronic component built in the wiring board, wherein
the fourth electronic component is a capacitor,
the fourth electronic component is stacked on a surface of the first electronic component facing to the third electronic component in the thickness direction defined for the core board, and
the second electronic component and the fourth electronic component are constituent components of the matching circuit.

18. The radio frequency module of claim 3, further comprising a fourth electronic component built in the wiring board, wherein
the fourth electronic component is a capacitor,
the fourth electronic component is stacked on a surface of the first electronic component facing to the third electronic component in the thickness direction defined for the core board, and
the second electronic component and the fourth electronic component are constituent components of the matching circuit.

19. The radio frequency module of claim 2, wherein
the third electronic component includes either a power amplifier or a low-noise amplifier.

20. The radio frequency module of claim 3, wherein
the third electronic component includes either a power amplifier or a low-noise amplifier.
